(19) United States
(12) Patent Application Publication
(10) Pub. No.: US 2026/0123376 A1
(43) Pub. Date: Apr. 30, 2026

(54) SEMICONDUCTOR STRUCTURE WITH TSV AND FABRICATING METHOD OF THE SAME

(71) Applicant: UNITED MICROELECTRONICS CORP., Hsin-Chu City (TW)

(72) Inventors: Chin-Chia Yang, Tainan City (TW); Da-Jun Lin, Kaohsiung City (TW); Fu-Yu Tsai, Tainan City (TW); Bin-Siang Tsai, Changhua County (TW); Chu-Fu Lin, Kaohsiung City (TW); Chuan-Lan Lin, Chiayi City (TW)

(73) Assignee: UNITED MICROELECTRONICS CORP., Hsin-Chu CIty (TW)

(21) Appl. No.: 18/985,058

(22) Filed: Dec. 18, 2024

(30) Foreign Application Priority Data
Oct. 30, 2024 (TW) 113141447

(51) Int. Cl. H01L 23/48; H01L 21/768; H01L 23/373; H01L 23/532

(52) U.S. Cl. CPC H10W 20/20; H10W 20/069; H10W 20/425; H10W 20/4405; H10W 20/4421; H10W 20/4432; H10W 20/48; H10W 40/254

(57) ABSTRACT

A semiconductor structure with a silicon through via (TSV) includes a semiconductor substrate. A TSV penetrates the semiconductor substrate. The TSV includes a metal layer, a barrier layer and an isolation layer. An end of the metal layer protrudes from a back side of the semiconductor substrate. A recess is disposed at one side of the end of the metal layer. A composite structure fills the recess. The composite structure includes a thermal conductive layer and a first dielectric layer. The thermal conductive layer contacts the sidewall of the end of the metal layer and contacts the barrier layer, the isolation layer and the semiconductor substrate. A first dielectric layer is disposed on the thermal conductive layer. A top surface of the first dielectric layer is aligned with the end of the metal layer. The thermal conductive layer includes aluminum nitride, aluminum oxide or diamond.

### BACKGROUND OF THE INVENTION

### 1. Field of the Invention

The invention relates to a semiconductor structure with a through silicon via (TSV) and a fabricating method of the same, and more particularly to a semiconductor structure with a TSV that has high heat dissipation ability and low parasitic capacitance, and a fabricating method of the same.

### 2. Description of the Prior Art

Manufacturing reliable, lightweight, compact, fast, multifunctional, efficient and low-cost semiconductor products has always been an important goal of the electronics industry. With the development of highly integrated semiconductor products, the number of input/output pins has increased significantly. The technology of connecting semiconductor chips through the use of silicon vias with small pitches has been widely developed. In this type of packaging structure, the connection between chips is achieved through TSVs.

The advantage of using TSV to package is that the chips can be stacked in three-dimension, and the size of chips can be greatly reduced. However, as the number of stacked chips increases, the density of metal lines also increases. In this way, due to the heating effect of current, the heat energy accumulation will be raised.

### SUMMARY OF THE INVENTION

According to a preferred embodiment of the present invention, a semiconductor structure with a TSV includes a semiconductor substrate. A TSV penetrates the semiconductor substrate, wherein the TSV includes a metal layer, a barrier layer and an isolation layer, and an end of the metal layer protrudes from a back side of the semiconductor substrate. A recess is disposed at one side of the end of the metal layer. A composite structure fills the recess. The composite structure includes a thermal conductive layer and a first dielectric layer. The thermal conductive layer contacts a sidewall of the end of the metal layer and contacts the barrier layer, the isolation layer and the semiconductor substrate. The first dielectric layer is disposed on the thermal conductive layer. A top surface of the first dielectric layer is aligned with the end of the metal layer, and the thermal conductive layer includes aluminum nitride, aluminum oxide or diamond.

A semiconductor structure with a TSV includes a semiconductor substrate. A TSV penetrates the semiconductor substrate. The TSV includes a metal layer, a barrier layer and an isolation layer, and an end of the metal layer protrudes from a back side of the semiconductor substrate. A recess is disposed at one side of the end of the metal layer. A composite structure fills the recess. The composite structure includes a thermal conductive layer and a first dielectric layer. The thermal conductive layer contacts a sidewall of the end of the metal layer and contacts the barrier layer, the isolation layer and the semiconductor substrate. The first dielectric layer is disposed on the thermal conductive layer. A top surface of the first dielectric layer is aligned with the end of the metal layer, and a thermal conductivity of the thermal conductive layer is between 5 and 350 W/m·k, and a dielectric constant of the first dielectric layer is smaller than 8.

A fabricating method of a semiconductor structure with a TSV includes providing a semiconductor substrate, wherein the semiconductor substrate includes a front side and a back side. Next, a TSV is formed to be embedded in the semiconductor substrate from the front side. The TSV includes a metal layer, a barrier layer and an isolation layer. Later, the back side of the semiconductor substrate is thinned to expose part of the TSV. The isolation layer and the barrier layer in the part of the TSV are removed and an end of the metal layer is remained. The end of the metal layer protrudes from the back side of the semiconductor substrate, and a recess is disposed at one side of the end of the metal layer. Finally, a thermal conductive layer and a first dielectric layer are formed sequentially to cover the recess. The thermal conductive layer contacts a sidewall of the end of the metal layer and contacts the barrier layer, the isolation layer and the semiconductor substrate. The first dielectric layer is disposed on the thermal conductive layer. A top surface of the first dielectric layer is aligned with the end of the metal layer. The thermal conductive layer includes aluminum nitride, aluminum oxide or diamond.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 7 depict a fabricating method of a semiconductor structure with a TSV according to a preferred embodiment of the present invention, wherein;

FIG. 2 is a fabricating stage in continuous of FIG. 1;

FIG. 3 is a fabricating stage in continuous of FIG. 2;

FIG. 4 is a fabricating stage in continuous of FIG. 3;

FIG. 5 is a fabricating stage in continuous of FIG. 4;

FIG. 6 is a fabricating stage in continuous of FIG. 5; and

FIG. 7 is a fabricating stage in continuous of FIG. 6.

### DETAILED DESCRIPTION

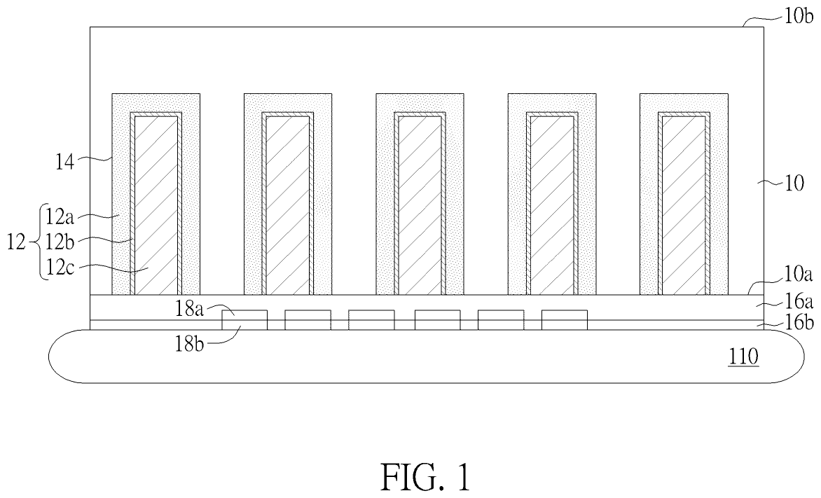

FIG. 1 to FIG. 7 depict a fabricating method of a semiconductor structure with a TSV according to a preferred embodiment of the present invention.

The fabricating method of the present invention is suitable for a wafer-level packaging (WLP). As shown in FIG. 1, a semiconductor substrate 10 is provided. The semiconductor substrate 10 includes a front side 10a and a back side 10b. The front side 10a is opposite to the back side 10b. Numerous active components, such as transistors (not shown), can be optionally disposed on the front side 10a. Next, a TSV 12 is formed to be embedded in the semiconductor substrate 10 from the front side 10a. In details, the TSV 12 is formed by etching the front side 10a of the semiconductor substrate 10 to form a trench 14. Then, an isolation layer 12a, a barrier layer 12b and a metal layer 12c are formed to fill in the trench 14 in sequence. The isolation layer 12a and the barrier layer 12b may be formed by using a physical vapor deposition process or a chemical vapor deposition process. The metal layer 12c can be formed by using a physical vapor deposition process, a chemical vapor deposition process or an electroplating process. Next, a dielectric layer 16a is formed to cover the front side 10a. Numerous conductive lines 18a are disposed in the dielectric layer 16a, and the conductive lines 18a include metal interconnects or metal bonding pads. The conductive lines 18a are electrically connected to the active components or the TSV 12. Conductive lines 18a are exposed from the top surface of the dielectric layer 16a. The semiconductor substrate 10 may be bonded to another semiconductor substrate 110. In details, the dielectric layer 16a on the semiconductor substrate 10 may be bonded to the dielectric layer 16b on the semiconductor substrate 110 to make conductive lines 18a to contact conductive lines 18b on semiconductor substrate 110.

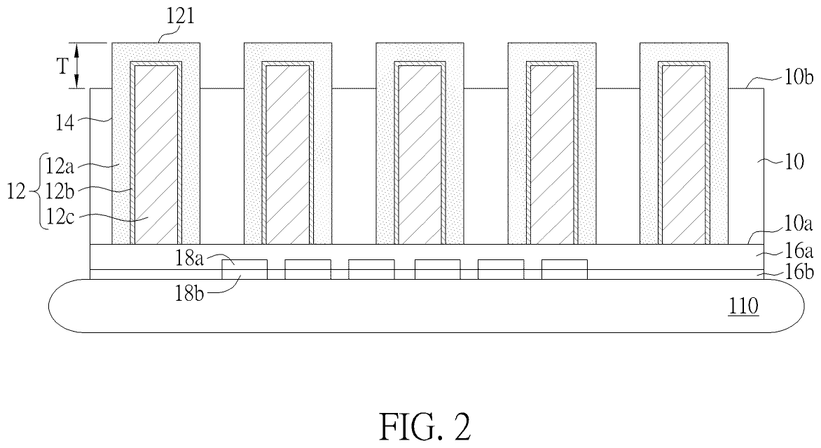

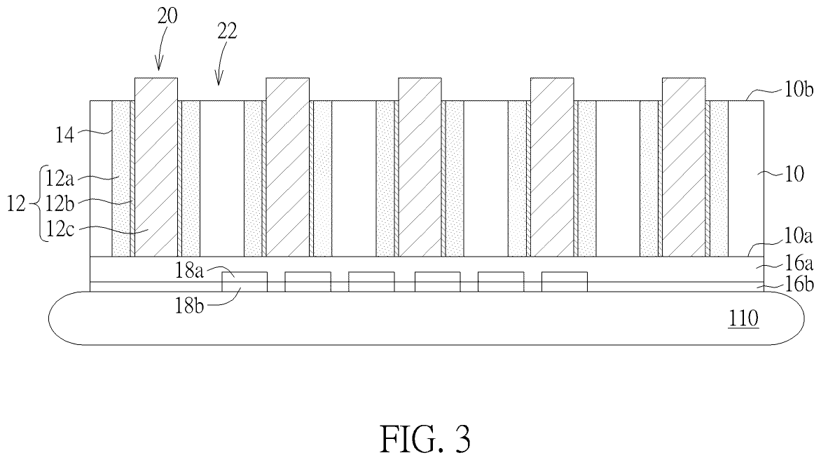

As shown in FIG. 2, the back side 10b of the semiconductor substrate 10 is thinned to expose part of a bottom 121 of the TSV 12, namely, the surface of the isolation layer 12a. According to a preferred embodiment of the present invention, the semiconductor substrate 10 can be thinned by using a dry etching. Now, the isolation layer 12a of the TSV 12 is exposed and the isolation layer 12a protrudes from the back side 10b of the semiconductor substrate 10. A distance T between the bottom 121 of the TSV 12 and the back side 10b of the semiconductor substrate 10 is about 4 to 6 micrometers. As shown in FIG. 3, the isolation layer 12a which is exposed and the barrier layer 12b which is exposed are completely removed, and the end 20 of the metal layer 12c is remained. At this point, the end 20 of the metal layer 12c protrudes from the back side 10b of the semiconductor substrate 10. Therefore, a recess 22 is formed at one side of the end 20 of the metal layer 12c. The removal method of the isolation layer 12a and the barrier layer 12b preferably includes a wet etching process. For example, the wet etching process may be performed by using buffered oxide etch (BOE) to remove the isolation layer 12a and the barrier layer 12b. The buffered oxide etch includes hydrofluoric acid.

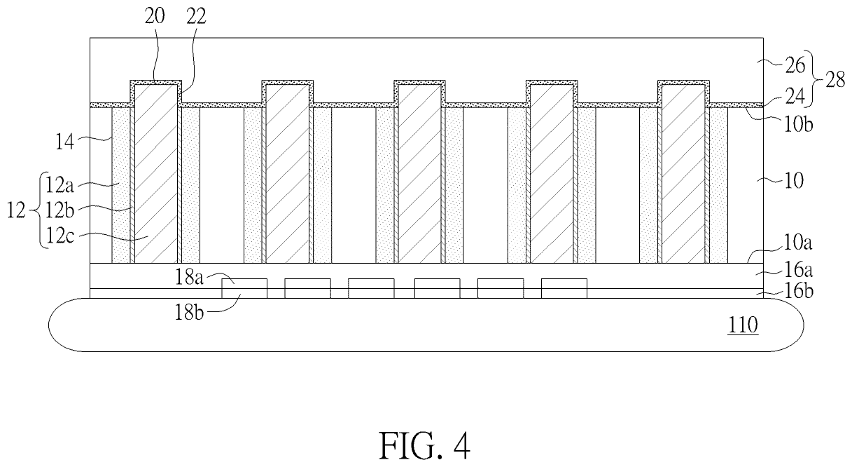

As shown in FIG. 4, a thermal conductive layer 24 is formed to conformally cover the end 20 of the metal layer 12c, the recess 22 and the back side 10b of the semiconductor substrate 10. The thermal conductive layer 24 contacts the metal layer 12c. Later, a first dielectric layer 26 is formed to cover the thermal conductive layer 24. The first dielectric layer 26 also covers the ends 20 of the metal layer 12c, the recess 22, and the back side 10b of the semiconductor substrate 10. The thermal conductive layer 24 is formed by a physical vapor deposition process, a chemical vapor deposition process or an atomic layer deposition process. The thermal conductive layer 24 preferably includes material(s) with a thermal conductivity coefficient between 5 and 350 W/m·k. For example, aluminum nitride, aluminum oxide or diamond can be used to form the thermal conductive layer 24. The first dielectric layer 26 can be formed by a physical vapor deposition process or a chemical vapor deposition process. The first dielectric layer 26 preferably includes material(s) with a dielectric constant less than 8, such as silicon nitride, silicon oxide, silicon oxynitride or silicon nitride carbide.

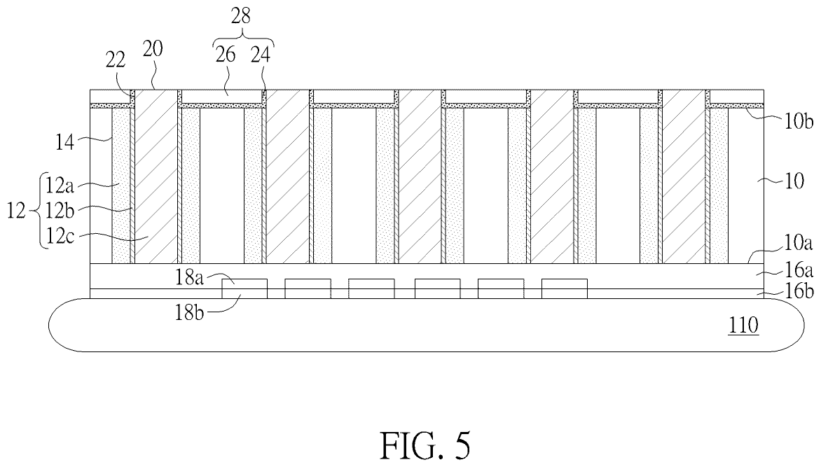

As shown in FIG. 5, the first dielectric layer 26 and the thermal conductive layer 24 outside of the recess 22 are removed. The removal of the first dielectric layer 26 and the thermal conductive layer 24 can be performed by using a chemical mechanical polishing process. After the chemical mechanical polishing process, the thermal conductive layer 24 and the first dielectric layer 26 together fill up the recess 22. The thermal conductive layer 24 contacts the sidewall of the end 20 of the metal layer 12c, the end of the barrier layer 12b, the end of the isolation layer 12a and the back side 10b of the semiconductor substrate 10. The thermal conductive layer 24 follows the profile of the recess 22 and is therefore U-shaped. The first dielectric layer 26 is disposed on the thermal conductive layer 24. The top surface of the first dielectric layer 26, two ends of the U-shape of the thermal conductive layer 24 and the end 20 of the metal layer 12c are aligned. The sidewall and the bottom of the first dielectric layer 26 are surrounded by the thermal conductive layer 24. Moreover, the thermal conductive layer 24 and the first dielectric layer 26 together form a composite structure 28.

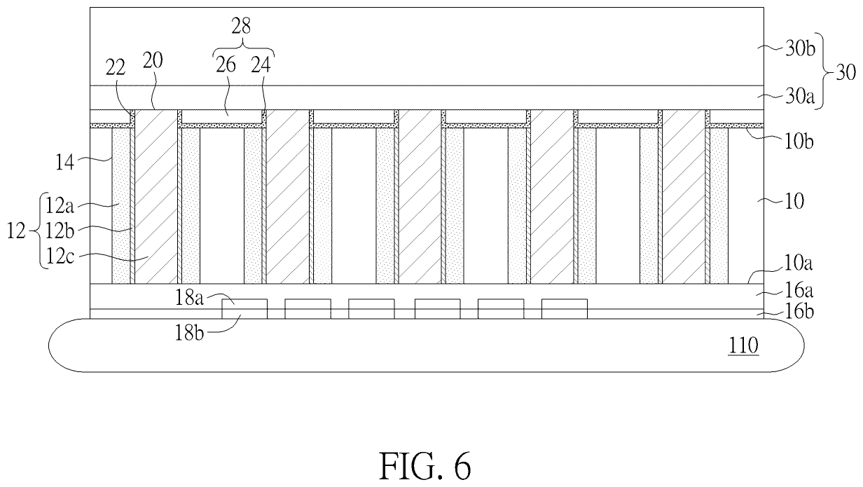

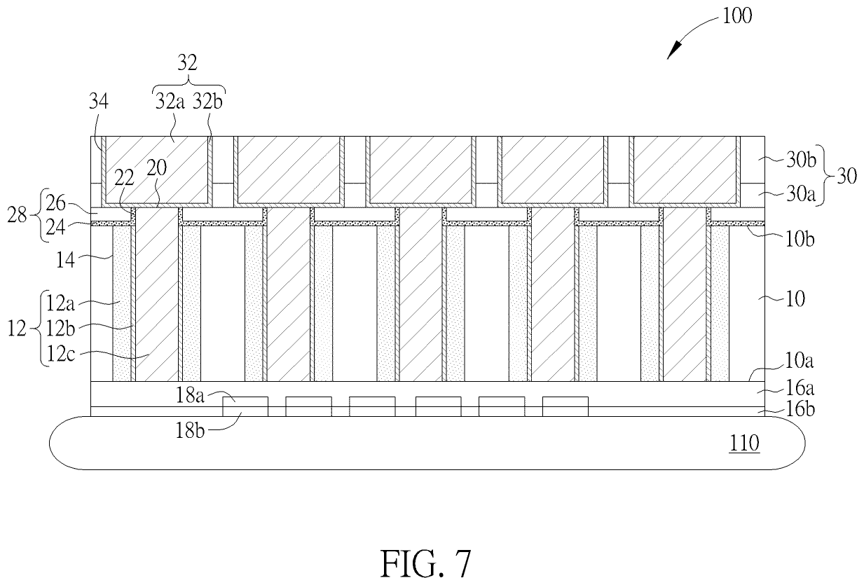

As shown in FIG. 6, a second dielectric layer 30 is formed to cover the first dielectric layer 26, the thermal conductive layer 24 and the TSV 12. The second dielectric layer 30 may be a single material layer or multiple material layers. As shown in FIG. 7, a conductive line 32 is formed to be embedded in the second dielectric layer 30. The conductive line 32 contacts the end 20 of the metal layer 12c, the thermal conductive layer 24 and the first dielectric layer 26. The conductive line 32 can be used as metal lines or metal pads of the redistribution layer (RDL). The conductive line 32 can be formed by etching the second dielectric layer 30 to form a trench 34. Later, the barrier layer 32b and the metal layer 32a are formed to fill the trench 34. The barrier layer 32b can be formed by a physical vapor deposition process, a chemical vapor deposition process or an atomic layer deposition process. The metal layer 32a can be formed by using a physical vapor deposition process, a chemical vapor deposition process or an electroplating process. Now, a semiconductor structure 100 with a TSV is completed.

As shown in FIG. 7, a semiconductor structure 100 with a TSV includes a semiconductor substrate 10. The semiconductor substrate 10 includes a silicon substrate, a germanium substrate, a gallium arsenide substrate, a silicon germanium substrate, an indium phosphide substrate, a gallium nitride substrate or a silicon carbide substrate. The semiconductor substrate 10 includes a front side 10a and a back side 10b. The front side 10a is opposite to the back side 10b. A TSV 12 penetrates the semiconductor substrate 10. The TSV 12 includes a metal layer 12c, a barrier layer 12b and an isolation layer 12a. The barrier layer 12b is disposed between the metal layer 12c and the isolation layer 12a. The isolation layer 12a contacts the semiconductor substrate 10. The end of the barrier layer 12b, the end of the isolation layer 12a and the back side 10b of the semiconductor substrate 10 are aligned. The end 20 of the metal layer 12c protrudes from the back side 10b of the semiconductor substrate 10. According to a preferred embodiment of the present invention, the metal layer 12c and the metal layer 32a respectively include copper, aluminum, titanium, tungsten or gold. The barrier layer 12b and the barrier layer 32b respectively include tantalum, tantalum nitride, titanium, or titanium nitride. The isolation layer 12a includes silicon nitride, silicon oxide, silicon oxynitride or silicon nitride carbide.

Moreover, a recess 22 is disposed at one side of the end 22 of the metal layer 12c. A composite structure 28 fills up the recess 22. The composite structure 28 includes a thermal conductive layer 24 and a first dielectric layer 26. The thermal conductive layer 24 contacts the sidewall of the end 22 of the metal layer 12c, the end of the barrier layer 12b, the end of the isolation layer 12a and the back side 10b of the semiconductor substrate 10. The first dielectric layer 26 is disposed on the thermal conductive layer 24. The top surface of the first dielectric layer 26 is aligned with the top surface of the end 20 of the metal layer 12c. Furthermore, a second dielectric layer 30 covers the composite structure 28, the TSV 12 and the semiconductor substrate 10. A conductive line 32 is embedded in the second dielectric layer 30. The conductive line 32 contacts the end 20 of the metal layer 12c, the thermal conductive layer 24 and the first dielectric layer 26. The thickness of the thermal conductive layer 24 is greater than 100 angstroms. The second dielectric layer 30 may be a single material layer or multiple material layers. The second dielectric layer 30 preferably includes silicon nitride, silicon oxide, silicon oxynitride, silicon nitride carbide or polymer. For example, the second dielectric layer 30 may include silicon nitride 30a and silicon oxide 30b stacked from bottom to top.

According to a preferred embodiment of the present invention, the thermal conductive layer 24 preferably includes a material with a thermal conductivity between 5 and 350 W/m·k, such as aluminum nitride, aluminum oxide or diamond. The first dielectric layer 26 preferably includes a material with a dielectric constant less than 8 such as silicon nitride, silicon oxide, silicon oxynitride or silicon nitride carbide. The thermal conductive layer 24 advantageously includes a material with a thermal conductivity coefficient between 200 and 350 W/m·k, such as aluminum oxide or diamond. The first dielectric layer 26 advantageously includes a material with a dielectric constant less than 4 such as silicon oxide. For example, in one of the preferred embodiments of the present invention, the metal layer 12c is copper, the thermal conductive layer 24 is aluminum nitride, the barrier layer 12b is tantalum nitride, and the isolation layer 12a is silicon oxide. The semiconductor substrate 10 is a silicon substrate. The first dielectric layer 26 is silicon oxide. The thermal conductivity of copper is about 400 W/m·k. The thermal conductivity of aluminum nitride is about 300 W/m·k. The thermal conductivity of tantalum nitride is about 5.5 W/m·k. The thermal conductivity of silicon oxide is between 1 and 2 W/m·k. The thermal conductivity of the silicon substrate is about 280 W/m·k. The dielectric constant of silicon oxide is about 4 or smaller than 4. The dielectric constant of aluminum nitride is about 13.

Currently, wafer packaging generally formed by stacking more than two wafers vertically. The wafers are electrically connected by using metal layers, and current flows through the metal layers will generate heat (due to heating effect of current). Therefore, the more wafers stacked together make the density of the metal layers larger, and more heat is generated by the heating effect of current. The present invention arranges aluminum nitride on one side of the copper conductive line of the TSV. Aluminum nitride is an isolation material and has a good thermal conductivity. When aluminum nitride contacts the copper conductive line, aluminum nitride can transfer the heat from the copper conductive line to the silicon substrate to help heat dissipation. Moreover, in addition to aluminum nitride, the reason why there is silicon oxide in the composite structure is that the dielectric constant of aluminum nitride is about 13. If aluminum nitride is used to fill up the recess completely, although there will be good heat conduction, but the parasitic capacitance between the TSVs will increase significantly. The dielectric constant of silicon oxide is about 4, so the present invention uses silicon oxide and aluminum nitride together to increase heat conduction while maintaining low parasitic capacitance. Therefore, the composite structure of the present invention needs to combine materials having a thermal conductivity within a predetermined range and materials having a dielectric constant within another predetermined range to achieve the best result of high heat dissipation and low parasitic capacitance. Furthermore, in the chemical mechanical polishing shown in FIG. 5, because chemical mechanical polishing has poor ability to polish aluminum nitride, but has good ability to polish silicon oxide, if aluminum nitride fills up the recess completely, polishing will be difficult to performed. Therefore, the present invention uses silicon oxide and aluminum nitride together to increase heat conduction and to make chemical mechanical polishing to become easier.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure with a silicon through via (TSV), comprising:
a semiconductor substrate;
a TSV penetrating the semiconductor substrate, wherein the TSV comprises a metal layer, a barrier layer and an isolation layer, and an end of the metal layer protrudes from a back side of the semiconductor substrate;
a recess disposed at one side of the end of the metal layer; and
a composite structure filling the recess, wherein the composite structure comprises a thermal conductive layer and a first dielectric layer, the thermal conductive layer contacts a sidewall of the end of the metal layer and contacts the barrier layer, the isolation layer and the semiconductor substrate, and wherein the first dielectric layer is disposed on the thermal conductive layer, a top surface of the first dielectric layer is aligned with the end of the metal layer, and the thermal conductive layer comprises aluminum nitride, aluminum oxide or diamond.

2. The semiconductor structure with a TSV of claim 1, further comprising:
a second dielectric layer covering the composite structure and the TSV; and
a conductive line embedded in the second dielectric layer, wherein the conductive line contacts the end of the metal layer, the thermal conductive layer and the first dielectric layer.

3. The semiconductor structure with a TSV of claim 2, wherein the second dielectric layer comprises silicon nitride, silicon oxide, silicon oxynitride, silicon nitride carbide or polymer.

4. The semiconductor structure with a TSV of claim 1, wherein the first dielectric layer comprises silicon nitride, silicon oxide, silicon oxynitride or silicon nitride carbide.

5. The semiconductor structure with a TSV of claim 1, wherein an end of the barrier layer, an end of the isolation layer and the back side of the semiconductor substrate are aligned.

6. The semiconductor structure with a TSV of claim 1, wherein the metal layer comprises copper, aluminum, titanium, tungsten or gold, the barrier layer comprises tantalum, tantalum nitride, titanium or titanium nitride, and the isolation layer comprises silicon nitride, silicon oxide, silicon oxynitride or silicon nitride carbide.

7. A semiconductor structure with a silicon through via (TSV), comprising:
a semiconductor substrate;
a TSV penetrating the semiconductor substrate, wherein the TSV comprises a metal layer, a barrier layer and an isolation layer, and an end of the metal layer protrudes from a back side of the semiconductor substrate;
a recess disposed at one side of the end of the metal layer; and
a composite structure filling the recess, wherein the composite structure comprises a thermal conductive layer and a first dielectric layer, the thermal conductive layer contacts a sidewall of the end of the metal layer and contacts the barrier layer, the isolation layer and the semiconductor substrate, and wherein the first dielectric layer is disposed on the thermal conductive layer, a top surface of the first dielectric layer is aligned with the end of the metal layer, and a thermal conductivity of the thermal conductive layer is between 5 and 350 W/m·k, and a dielectric constant of the first dielectric layer is smaller than 8.

8. The semiconductor structure with a TSV of claim 7, further comprising:
a second dielectric layer covering the composite structure and the TSV; and
a conductive line embedded in the second dielectric layer, wherein the conductive line contacts the end of the metal layer, the thermal conductive layer and the first dielectric layer.

9. The semiconductor structure with a TSV of claim 8, wherein the second dielectric layer comprises silicon nitride, silicon oxide, silicon oxynitride, silicon nitride carbide or polymer.

10. The semiconductor structure with a TSV of claim 7, wherein the first dielectric layer comprises silicon nitride, silicon oxide, silicon oxynitride or silicon nitride carbide.

11. The semiconductor structure with a TSV of claim 7, wherein an end of the barrier layer, an end of the isolation layer and the back side of the semiconductor substrate are aligned.

12. The semiconductor structure with a TSV of claim 7, wherein the thermal conductivity of the thermal conductive layer is between 200 and 350 W/m·k, and the dielectric constant of the first dielectric layer is smaller than 4.

13. The semiconductor structure with a TSV of claim 7, wherein the metal layer comprises copper, aluminum, titanium, tungsten or gold, the barrier layer comprises tantalum, tantalum nitride, titanium or titanium nitride, the isolation layer comprises silicon nitride, silicon oxide, silicon oxynitride or silicon nitride carbide.

14. A fabricating method of a semiconductor structure with a silicon through via (TSV), comprising:
providing a semiconductor substrate, wherein the semiconductor substrate comprises a front side and a back side;
forming a TSV to be embedded in the semiconductor substrate from the front side, wherein the TSV comprises a metal layer, a barrier layer and an isolation layer;
thinning the back side of the semiconductor substrate to expose part of the TSV;
removing the isolation layer and the barrier layer in the part of the TSV and remaing an end of the metal layer, wherein the end of the metal layer protrudes from the back side of the semiconductor substrate, and a recess is disposed at one side of the end of the metal layer; and
forming a thermal conductive layer and a first dielectric layer sequentially to cover the recess, wherein the thermal conductive layer contacts a sidewall of the end of the metal layer and contacts the barrier layer, the isolation layer and the semiconductor substrate, and wherein the first dielectric layer is disposed on the thermal conductive layer, a top surface of the first dielectric layer is aligned with the end of the metal layer, and the thermal conductive layer comprises aluminum nitride, aluminum oxide or diamond.

15. The fabricating method of a semiconductor structure with a TSV of claim 14, further comprising:
forming a second dielectric layer covering the composite structure and the TSV; and
forming a conductive line embedded in the second dielectric layer, wherein the conductive line contacts the end of the metal layer, the thermal conductive layer and the first dielectric layer.

16. The fabricating method of a semiconductor structure with a TSV of claim 15, wherein the second dielectric layer comprises silicon nitride, silicon oxide, silicon oxynitride, silicon nitride carbide or polymer.

17. The fabricating method of a semiconductor structure with a TSV of claim 14, wherein the first dielectric layer comprises silicon nitride, silicon oxide, silicon oxynitride or silicon nitride carbide.

18. The fabricating method of a semiconductor structure with a TSV of claim 14, wherein the metal layer comprises copper, aluminum, titanium, tungsten or gold, the barrier layer comprises tantalum, tantalum nitride, titanium or titanium nitride, and the isolation layer comprises silicon nitride, silicon oxide, silicon oxynitride or silicon nitride carbide.

19. The fabricating method of a semiconductor structure with a TSV of claim 14, wherein a thermal conductivity of the thermal conductive layer is between 5 and 350 W/m·k, and a dielectric constant of the first dielectric layer is smaller than 8.

20. The fabricating method of a semiconductor structure with a TSV of claim 14, wherein a thermal conductivity of the thermal conductive layer is between 200 and 350 W/m·k, and a dielectric constant of the first dielectric layer is smaller than 4.
